(19) United States
(12) Patent Application Publication
(10) Pub. No.: US 2009/0152546 A1
(43) Pub. Date: Jun. 18, 2009

(54) WAFER WITH SCRIBE LANES COMPRISING ACTIVE CIRCUITS FOR DIE TESTING OF COMPLEMENTARY SIGNAL PROCESSING PARTS

(75) Inventors: Herve Marie, Ver Sur Mer (FR); Sofiane Ellouz, Caen (FR)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/067,982

(22) PCT Filed: Sep. 25, 2006
(86) PCT No.: PCT/IB2006/053477

§ 371 Date: Oct. 24, 2008

(30) Foreign Application Priority Data
Sep. 27, 2005 (EP) 05300779.5
Sep. 25, 2006 (IB) PCT/IB2006/053477

(51) Int. Cl. H01L 23/544

(52) U.S. Cl. 257/48; 257/E23.179

(57) ABSTRACT

A wafer (W) comprises at least one die (D1-D6) comprising first (P1) and second (P2) complementary signal processing parts, scribe lanes (SL) defined between and around each die, and coupling means (CM) defined in at least a part of the scribe lanes (SL) and connecting i) the first part output of one of the dies (D1) to a second part input of at least one of the dies (D2) so that the first part output feeds the second part input with first output signals when it is fed with first input signals and configured to work, and so that the output of the fed second part (P2) delivers second output signals when it is configured to work, and/or ii) the second part output of one of the dies (D1) to a first part input of at least one of the dies (D2) so that the second part output feeds the first part input with second output signals when it is fed with second input signals and configured to work and so that the output of the fed first part (P1) delivers first output signals when it is configured to work.

### FIELD OF THE INVENTION

The present invention relates to the domain of integrated circuits, and more precisely to the test of integrated circuits (or dies) defined in wafers.

### BACKGROUND OF THE INVENTION

As it is known by one skilled in the art dies must be tested before being integrated with electronic equipments. For practical reasons they are tested when they still belong to their wafer, i.e. before being separated one from the other by a cut-off process along scribe lanes (or lines) defined therebetween.

Dies are tested alone or in parallel by means of a probe card controlled by automated test equipment (ATE). To be tested, a die must be provided with internal pads connected to some of its integrated components, generally through internal test circuits that are only used during the test.

When a die comprises first and second complementary signal processing parts (or dual parts), each part must be tested. This applies to any type of dual circuit, such as transmitting and receiving paths (in case of radio communication equipment), digital to analog converter (DAC) and analog to digital converter (ADC), or else demodulator and modulator, for instance.

Most often, dual parts (such as receiving and transmitting paths) are tested independently. Sometimes, a loop back configuration is used. In this case either a radiofrequency (RF) transmit signal is connected to the RF receive input, or the receive base-band output signal of the receiving path is fed back to the input of the transmitting path.

An advantage is that both receiving path and transmitting path are tested at the same time, which reduces test time and, therefore, cost. Another advantage is that there is no more need for example to generate an RF signal from the ATE, which reduces cost of the ATE. The connections run through the needles and through some adaptive circuits located on the probe card to which the needles are connected.

Such a loop back configuration may require definition of some internal test circuits within the dies, to ease wafer testing. The die cost in terms of area for adding these internal test circuits might be too high.

So, the object of this invention is to improve the situation.

### SUMMARY OF THE INVENTION

For this purposes, it provides a wafer comprising at least one die comprising first and second complementary signal processing parts, this first part having an input to receive first input signals and an output to deliver first output signals and this second part having an input to receive second input signals and an output to deliver second output signals, and scribe lanes defined between and around each die.

By “first and second complementary signal processing parts” is meant a first signal processing part of a die delivering output signals which can feed the input of a second signal processing part of the same die or of another die (possibly through an intermediate signal processing means), which can itself deliver output signals which can feed the input of a first signal processing part of the same die or of another die (possibly through an intermediate signal processing means). So, they might be a transmitter path and a receiver path or a transceiver, or a digital to analog converter (DAC) and an analog to digital converter (ADC), or else a demodulator and a modulator, for instance.

This wafer is characterized in that it comprises at least a coupling means defined in at least a part of the scribe lanes and connecting:
the first part output of one of the wafer dies to a second part input of at least one of the wafer dies (possibly the same one) so that this first part output feeds this second part input with first output signals when it is fed with first input signals and configured to work, and so that the output of the fed second part delivers second output signals when it is configured to work, and/or
the second part output of one of the wafer dies to a first part input of at least one of the wafer dies (possibly the same one) so that this second part output feeds this first part input with second output signals when it is fed with second input signals and configured to work and so that the output of the fed first part delivers first output signals when it is configured to work.

The wafer according to the invention may have additional characteristics considered separately or combined, and notably:
it may comprise at least a first conductive track defined in at least a part of the scribe lanes and arranged to feed the first part of each die to be tested with first input (test) signals and/or the second part of each die to be tested with second input (test) signals;
it may comprise at least one bus defined in at least a part of the scribe lanes and arranged to feed each die to be tested with configuration signals to make it use either its first part or its second part;
   each bus may comprise switch means arranged to selectively feed the dies with configuration signals;
it may comprise at least a second conductive track defined in at least a part of the scribe lanes and arranged to collect the delivered second output signals of each die to be tested and/or the first output signals of each die to be tested;
it may comprise at least one group of at least three dies associated to a coupling means comprising at least one switch means arranged to selectively feed the second part input of one die of this group with first output signals delivered by the first part output of another selected die of this group;
   each group may comprise first, second, third and fourth dies and may be associated to a coupling means comprising one switch means having two inputs connected to the first part outputs of the first and third dies respectively and two outputs connected to the second part inputs of the second and fourth dies respectively and arranged to feed the second part output of either the second die or the fourth die with the first output signals delivered by the first part output of either the first die or the third die;
      the first and third dies of each group may each be coupled to a first bus through a dedicated switch means, and the second and fourth dies of each group may each be coupled to a second bus through a dedicated switch means;
it may comprise a first group of at least two odd dies and a second group of at least two even dies, both associated to a coupling means comprising at least three switch means arranged to selectively feed the second part input of one selected die of the second group with first output signals delivered by the first part output of a selected die of said first group;
   most of the switch means of the coupling means may comprise two bidirectional inputs/outputs connected, on the one hand, to the output of the first part of one odd die of the first group and to an input/output of a neighboring switch means respectively, and on the other hand, to the input of the second part of one even die of the second group and to an input/output of another neighboring switch means;
   each odd die of each first group may be coupled to a first bus through a dedicated switch means, and each even die of each group may be coupled to a second bus through a dedicated switch means;
its coupling means may comprise at least one signal processing means arranged to apply at least one chosen processing to the first output signals delivered by a first part output, before they feed a second part input, and/or to the second output signals delivered by a second part output, before they feed a first part input.

### BRIEF DESCRIPTION OF THE DRAWINGS

Other features and advantages of the invention will become apparent on examining the detailed specifications hereafter and the appended drawings, wherein:

FIG. 1 schematically illustrates a wafer according to the invention,

FIG. 2 schematically illustrates a first example of embodiment of a part of a wafer according to the invention,

FIG. 3 schematically illustrates a second example of embodiment of a part of a wafer according to the invention, and

FIG. 4 schematically illustrates a third example of embodiment of a part of a wafer according to the invention.

The appended drawings may not only serve to complete the invention, but also to contribute to its definition, if need be.

### DESCRIPTION OF THE PREFERRED EMBODIMENTS

The invention aims at reducing the number of integrated components that are defined in dies exclusively for test purposes, when they still belong to their wafer and when they comprise first and second complementary signal processing parts.

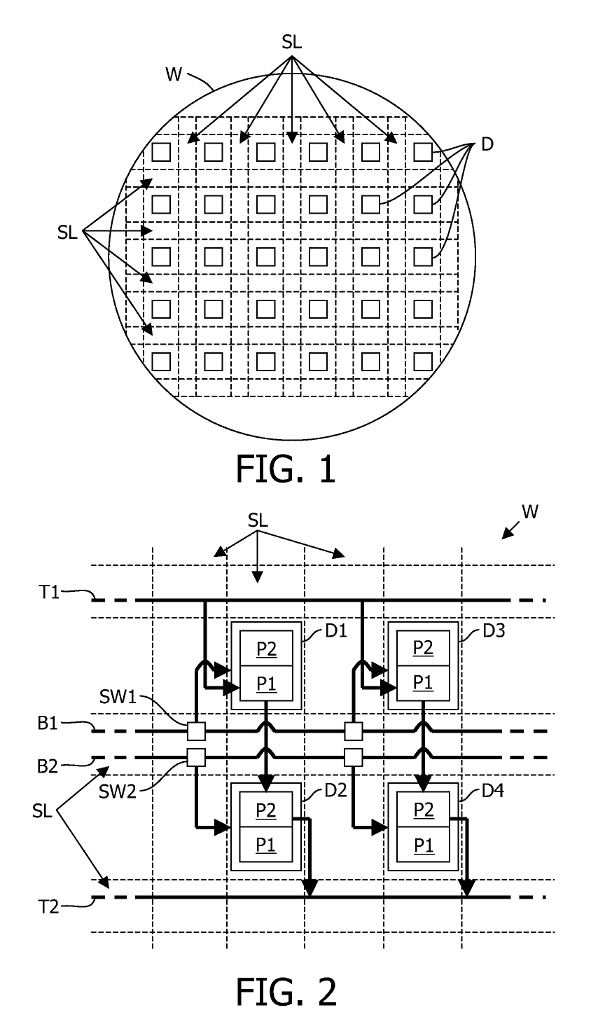

As is schematically illustrated in FIG. 1, one or more dies (or integrated circuits) D are usually defined in a wafer W, for instance of the semiconductor type. These dies are interspaced according to a chosen template (or pattern) which allows their cut-off along scribe lanes (or lines) SL (schematically materialized by dotted lines in FIG. 1). In other words, because of the space left between the independent dies D, scribe lanes SL are defined between and around the independent dies D.

In the following description it will be considered that the wafer comprises several dies that are intended to be integrated with the transceiver of communication equipment such as a mobile telephone adapted to radio communication, for instance in a GSM or UMTS network. But it is important to notice that the invention is not limited to this type of electronic equipment and to wafers comprising several dies. It applies to any circuit comprising complementary signal processing parts implementing complementary functions, such as transmitter path/receiver path, DAC/ADC and demodulator/modulator, for instance. Moreover, it applies to any type of signal to be processed, such as radiofrequency (RF) signals, analog signals and digital signals, for instance.

Moreover, in the following description it will be considered that each die D (defined in the wafer W) comprises first and second complementary RF signal processing parts which are respectively a transmitting path, having an input to receive first input signals (for instance baseband signals) and an output to deliver first output signals (for instance RF signals), and a receiving path having an input to receive second input signals (for instance RF signals) and an output to deliver second output signals (for instance baseband signals).

The invention offers to integrate at least some of the integrated circuits, which are required for testing dies, with some of the scribe lanes SL.

More precisely and as illustrated in the first example of embodiment sketched in FIG. 2, a wafer W according to the invention comprises, in addition to its die(s), at least a coupling means CM defined in chosen parts of the wafer scribe lanes SL.

The coupling means CM is arranged to connect:
the output of the first part P1 of one of the wafer dies D to the input of the second part P2 of at least one of the wafer dies D (possibly the same one) so that this first part output feeds this second part input with first output signals when it is fed with first input signals and configured to work, and so that the output of the fed second part delivers second output signals when it is configured to work, and/or
the output of the second part P2 of one of the wafer dies D to the input of the first part P1 of at least one of the wafer dies D (possibly the same one) so that this second part output feeds this first part input with second output signals when it is fed with second input signals and configured to work, and so that the output of the fed first part delivers first output signals when it is configured to work.

As illustrated in FIG. 2, the wafer W according to the invention may also comprise at least one first conductive track T1 and/or at least one second conductive track T2 and/or at least one bus B1, B2, which are all defined in chosen parts of the wafer scribe lanes SL.

The following description of the first example illustrated in FIG. 2 will only be focused on the case where the first parts P1 of dies are first tested so that the signals they deliver feed the input of one or more second parts P2 of other dies also for test purposes. But the invention also applies to the opposite case where the second parts P2 of dies are first tested so that the signals they deliver feed the input of one or more first parts P1 of other dies also for test purposes.

A first conductive track T1 is connected to the input of the first part (transmitting path) P1 of each or some dies D to be tested in order to feed it (or them) with first input signals (for instance baseband signals).

In the example illustrated in FIG. 2, two buses B1 and B2 have been defined. But this is not mandatory. Only one bus is mandatory (in cases where buses are used). Two buses are preferred when the number of dies D to be tested is important. For instance the first B1 and second B2 buses are coupled to a control input of each odd die D1 and even die D2 to be tested respectively in order to feed it with configuration signals, when required. The configuration signals are intended to configure a die D1 or D2 so that it works either with its first part P1 or with its second part P2.

For instance and as illustrated in FIG. 2, each bus Bi (i=1 or 2) may be coupled to each of its dies (D1, D3, D5 . . . ) or (D2, D4, D6 . . . ) through an active switch means SWi. So, when a die D is not under test the corresponding active switch means SWi is in an open state preventing it to receive configuration signals, and when a die D is under test the corresponding active switch means SWi is in a closed state allowing it to receive configuration signals defining its working mode.

As mentioned before, the (or each) coupling means CM is arranged to couple the output of the first part P1 of at least one die D1 and/or D3 to the input of the second part P2 of at least one other die D2 and/or D4.

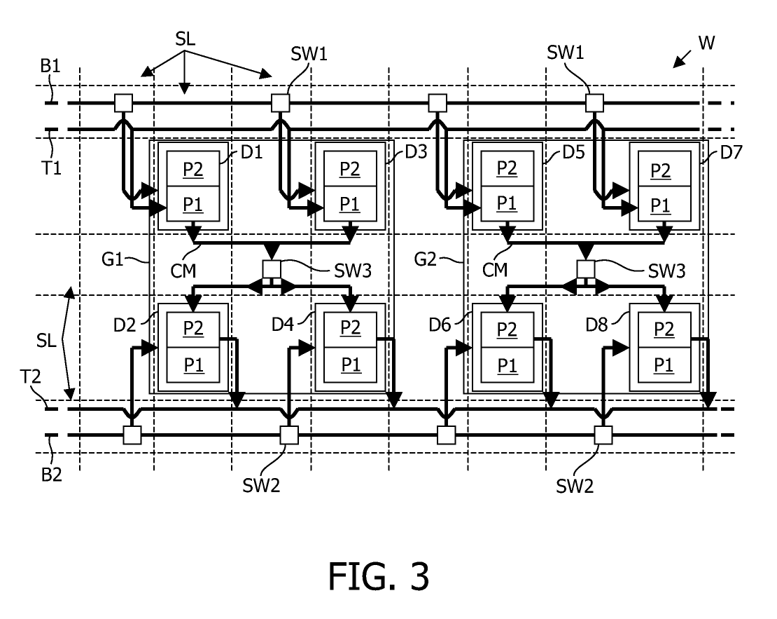

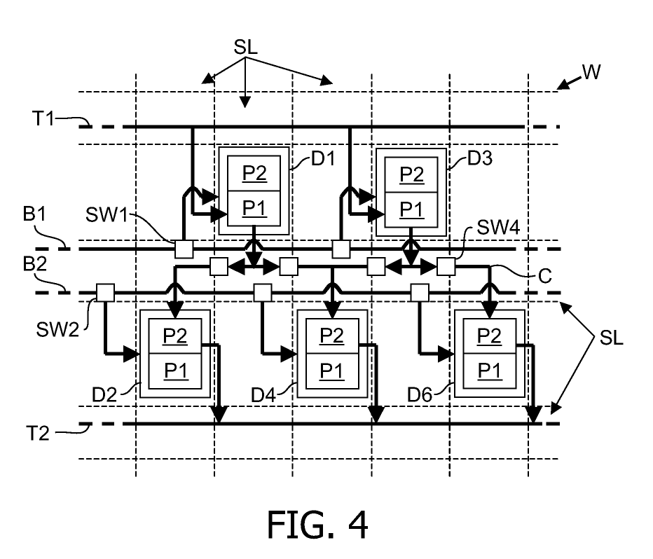

In the first example illustrated in FIG. 2 the wafer W comprises coupling means CM defined to couple the output of the first part P1 of one die D1 (or D3) to the input of the second part P2 of another die D2 (or D4). But as will be described later on with reference to FIGS. 3 and 4, other types of coupling means CM may be used.

So, when a die D1 (or D3) is configured through the (first) bus B1 to work with its first part P1 and a second die D2 (or D4), coupled to this die D1 (or D3) through the coupling means CM, is configured through the (second) bus B2 to work with its second part P2, the die D1 (or D3) receives first input signals (for instance baseband signals) on the input of its first part P1 and delivers first output signals (for instance RF signals) on the output of its first part P1, and the die D2 (or D4) receives these first output signals on the input of its second part P2, through the coupling means CM, and delivers second output signals (for instance baseband signals) on the output of its second part P2. Therefore, the result of the test of the first part P1 of a die D1 (or D3) is used to test the second part P2 of another die D2 (or D4).

A second conductive track T2 is connected to the output of the second part (receiving path) P2 of each or some dies D to be tested in order to collect the second output signals (for instance baseband signals) it delivers (they deliver).

By defining sequences of states for the different switch means SWi and corresponding sequences of configuration signals for the different dies D it is thus possible to test automatically the first and second parts P1, P2 of every die D, without mechanically moving the probe card.

Reference is now made to FIG. 3 to describe a second example of embodiment of a wafer W according to the invention. The main difference between this second example and the first one lies in the type of coupling means CM that are used to couple dies D.

In the following description of the second example illustrated in FIG. 3, it will be also focused only on the case where the first parts P1 of dies are first tested so that the signals they deliver feed the input of several second parts P2 of other dies also for test purposes. But the invention also applies to the opposite case where the second parts P2 of dies are first tested so that the signals they deliver feed the input of several first parts P1 of other dies also for test purposes.

This second example aims at overcoming a drawback of the first example. Indeed, in the first example, if the test of a transmitting part (P1) of a first die with the receiving part (P2) of a second die fails, then it is not possible to know whether the first die and/or the second die is/are faulty. So the second example adds to the first example the capability to connect the first part P1 of a die to the second parts P2 of several other dies and conversely, to connect the second part P2 of a die to the first parts P1 of several other dies, to determine whether it is the first part or the second part of a die that is faulty.

For this purposespurposess, the wafer W comprises at least two groups Gj (here j=1 and 2) of at least three dies coupled by means of a coupling means CM comprising at least one switch means SW3.

Such a switch means SW3 comprises at least two inputs respectively connected to the output of the first part P1 of at least two dies D1 and D3 (in group G1), or D5 and D7 (in group G2), and at least one output connected to the input of the second part P2 of at least one other die D2 and D4 (in the same group G1), or D6 and D8 (in the same group G2).

Each switch means SW3 is arranged to selectively feed the second part input of one die of its corresponding group Gj with the first output signals delivered by the first part output of another selected die of this group Gj.

In the second example illustrated in FIG. 3, each group Gj comprises first D1 (or D5), second D2 (or D6), third D3 (or D7) and fourth D4 (or D8) dies. In each group Gj the coupling means comprises one switch means SW3 which has two inputs connected to the first part outputs of the first and third dies D1, D3 (or D5 and D7 respectively) and two outputs connected to the second part outputs of the second and fourth dies D2, D4 (or D6 and D8 respectively).

With such an arrangement four combinations of dies may be tested in each group Gj depending on the chosen states of the corresponding switch means SW3. Indeed, the output of the first part P1 of the first die D1 (or D5) may be coupled to the input of the second part P2 of either the second die D2 (or D6) or the fourth die D4 (or D8) to feed it with the first output signals it delivers, and the output of the first part P1 of the third die D3 (or D7) may be coupled to the input of the second part P2 of either the second die D2 (or D6) or the fourth die D4 (or D8) to feed it with the first output signals it delivers.

As in the first example, one uses first T1 and second T2 conductive tracks. A first conductive track T1 feeds the input of the first part P1 of the odd dies D1 and D3 (or D5 and D7) of each group Gj with the first input signals (for instance baseband signals). A second conductive track T2 collects the second output signals (for instance baseband signals) delivered by the output of the second part P2 of the even dies D2 and D6 (or D4 and D8).

Although this is not illustrated in FIG. 3 for clarity, another first conductive track may be used to feed the input of the first part P1 of the even dies D2 and D4 (or D6 and D8) of each group Gj with the first input signals (for instance baseband signals), and another second conductive track may be used to collect the second output signals (for instance baseband signals) delivered by the output of the second part P2 of the odd dies D1 and D3 (or D5 and D7) of each group Gj.

Moreover, as in the first example, one preferably uses first and second buses B1, B2. But this is not mandatory. Two buses are preferred when the number of dies D to be tested is important. For instance the first and second buses B1, B2 are coupled to a control input of each odd die D1 and D3 (or D5 and D7) and even die D2 and D4 (or D6 and D8) respectively to feed it with configuration signals, when required.

For instance and as illustrated in FIG. 3, each bus Bi (i=1 or 2) may be coupled to each of its dies (D1, D3, D5, D7 . . . ) or (D2, D4, D6, D8 . . . ) through an active switch means SWi. So, when a die D is not under test the corresponding active switch means SWi is in an open state preventing it to receive configuration signals, and when a die D is under test the corresponding active switch means SWi is in a closed state allowing it to receive configuration signals defining its working mode.

By defining sequences of states for the different switch means SWi and SW3 and corresponding sequences of configuration signals for the different dies D it is thus possible to test automatically the first P1 and second P2 parts of every die D, without mechanically moving the probe card.

This second example is of great interest because it facilitates the discovery of a faulty part P1 or P2 in each tested die D, and reduces notably the yield loss during die tests.

Reference is now made to FIG. 4 to describe a third example of embodiment of a wafer W according to the invention. The main difference between this third example and the first one also lies in the type of coupling means CM that are used to couple dies D.

In the following description of the third example illustrated in FIG. 4, the focus will only be on the case where the first parts P1 of dies are first tested so that the signals they deliver feed the input of several second parts P2 of other dies also for test purposes. But the invention also applies to the opposite case where the second parts P2 of dies are first tested so that the signals they deliver feed the input of several first parts P1 of other dies also for test purposes.

In this third example, the wafer W comprises a first group of at least two odd dies D1, D3, . . . and a second group of at least two even dies D2, D4, D6, . . . . The output of the first part P1 of each odd die D1 (or D3) is coupled to the input of the second part of each even die D2 (or D4 or D6) to be tested, by means of a common coupling means CM comprising one pair of switch means SW4 associated to each odd die D1 (or D3).

Each switch means SW4 comprises two bidirectional inputs/outputs respectively connected, on the one hand, to the output of the first part P1 of one odd die D1 (or D3) and to an input/output of the neighboring switch means SW4 (except for the first and the last one), and on the other hand, to the input of the second part P2 of one even die D2 (or D4 or D6) and to an input/output of another neighboring switch means SW4 (except for the first and the last one). So, each switch means SW4 is arranged to selectively feed either the second part input of one even die D2 (or D4 or D6) or a neighboring switch means SW4 with the first output signals delivered by the first part output of the odd die D1 (or D3) or of a distant odd die.

With such an arrangement any combination of odd and even dies may be tested depending on the chosen states of each switch means SW4.

As in the first example, one uses first and second conductive tracks T1, T2. A first conductive track T1 feeds the input of the first part P1 of the odd dies D1 and D3 (or D5 and D7) with the first input signals (for instance baseband signals). A second conductive track T2 collects the second output signals (for instance baseband signals) delivered by the output of the second part P2 of the even dies D2 and D6 (or D4 and D8).

Although this is not illustrated in FIG. 4 for clarity, another first conductive track may be used to feed the input of the first part P1 of the even dies D2, D4, D6 and D8 with the first input signals (for instance baseband signals), and another second conductive track may be used to collect the second output signals (for instance baseband signals) delivered by the output of the second part P2 of the odd dies D1 and D3.

Moreover, as in the first example, one preferably uses first and second buses B1, B2. But this is not mandatory. Two buses are preferred when the number of dies D to be tested is important. For instance the first and second buses B1, B2 are respectively coupled to a control input of each odd die D1 and D3 and even die D2, D4, and D6 to feed it with configuration signals, when required.

For instance and as illustrated in FIG. 4, each bus Bi (i=1 or 2) may be coupled to each of its odd dies (D1, D3, D5, D7 . . . ) or even dies (D2, D4, D6, D8 . . . ) through an active switch means SWi. So, when a die D is not under test the corresponding active switch means SWi is in an open state preventing it to receive configuration signals, and when a die D is under test the corresponding active switch means SWi is in a closed state allowing it to receive configuration signals defining its working mode.

By defining sequences of states for the different switch means SWi and SW4 and corresponding sequences of configuration signals for the different dies D it is thus possible to test automatically the first and second parts P1, P2 of every die D, without mechanically moving the probe card.

This third example is also of interest because it facilitates the discovery of a faulty part P1 or P2 in each tested die D, and minimizes yield loss during die tests.

In each example of embodiment a coupling means comprises conductive tracks and possibly at least one active switch means. But for test purposes a coupling means may also comprise one or more components dedicated to signal processing, such as a load or a voltage level controller in case of RF signals, or a frequency converter, or buffers or digital logic in case of digital signals, or else amplification circuit or filters in case of analog signals. These signal processing components may allow to apply at least one chosen processing to the first output signals delivered by the output of a first part P1, before they feed the input of a second part P2, and/or to the second output signals delivered by the output of a second part P2, before they feed the input of a first part P1.

Moreover, it is important to notice that in each example of embodiment:
in the case where one does not use any first conductive track T1, the first input signals dedicated to testing of the first parts P1 is directly provided on the first parts P1 by means of a probe card (for instance through needles, or with any other probing technique). This also applies to the case where the second parts P2 are tested first,
in the case where one does not use any second conductive track T2, the second output signals delivered by the tested second parts P2 are directly collected on the second parts P2 by means of a probe card (for instance through needles, or with any other probing technique). This also applies to the case where the signals to be collected are delivered by the first parts P1,
in the case where one does not use any bus B, the control input of the dies D are directly fed with configuration signals by means of a probe card (for instance through needles, or with any other probing technique).

The dies may be realized in the wafer in CMOS or BiCMOS technology or in any technology used in chip industry fabrication.

The invention is not limited to the embodiments of the wafer described above, only used as examples, but it encompasses all alternative embodiments which may be considered by one skilled in the art to be within the scope of the claims hereafter.

So, in the preceding description parts of wafers have been described in the scribe lanes of which buses and conductive tracks were defined either for feeding the first part of some dies with first input signals or for collecting the second output signals delivered by the second part of some other dies, for clarity. But, for the first and second parts of each die to be testable, some other conductive tracks may be used.

1. Wafer, comprising at least one die, comprising first and second complementary signal processing parts, said first part having an input to receive first input signals and an output to deliver first output signals and said second part having an input to receive second input signals and an output to deliver second output signals, and scribe lanes defined between and around said die, characterized in that it comprises at least coupling means defined in at least a part of said scribe lanes and connecting i) the first part output of one of said dies to a second part input of at least one of said dies so that said first part output feeds said second part input with first output signals when it is fed with first input signals and configured to work and so that the output of the fed second part delivers second output signals when it is configured to work, and/or ii) the second part output of one of said dies to a first part input of at least one of said dies so that said second part output feeds said first part input with second output signals when it is fed with second input signals and configured to work and so that the output of the fed first part delivers first output signals when it is configured to work.

2. Wafer according to claim 1, characterized in that it comprises at least one first conductive track defined in at least a part of said scribe lanes and arranged to feed the first part of each die to be tested with first input signals and/or the second part of each die to be tested with second input signals.

3. Wafer according to claim 1, characterized in that it comprises at least one bus defined in at least a part of said scribe lanes and arranged to feed each die to be tested with configuration signals to make it use either its first part or its second part.

4. Wafer according to claim 3, characterized in that each bus comprises switch means arranged to selectively feed said dies with configuration signals.

5. Wafer according to claim 1, characterized in that it comprises at least one second conductive track defined in at least a part of said scribe lanes and arranged to collect said delivered second output signals of each die to be tested and/or said first output signals of each die to be tested.

6. Wafer according to claim 1, characterized in that it comprises at least one group of at least three dies associated to a coupling means comprising at least one switch means arranged to selectively feed the second part input of one die of this group with first output signals delivered by the first part output of another selected die of said group.

7. Wafer according to claim 6, characterized in that each group comprises first, second, third and fourth dies and is associated to a coupling means comprising one switch means having two inputs connected to the first part outputs of said first and third dies respectively and two outputs connected to the second part inputs of said second and fourth dies respectively and arranged to feed the second part output of either said second die or said fourth die with the first output signals delivered by the first part output of either said first die or said third die.

8. Wafer according to claim 4, characterized in that said first and third dies of each group are each coupled to a first bus through a dedicated switch means, and said second and fourth dies of each group are each coupled to a second bus through a dedicated switch means.

9. Wafer according to claim 1, characterized in that it comprises a first group of at least two odd dies and a second group of at least two even dies, both associated to a coupling means comprising at least three switch means arranged to selectively feed the second part input of one selected die of the second group with first output signals delivered by the first part output of a selected die of said first group.

10. Wafer according to claim 9, characterized in that most of said switch means comprise two bidirectional inputs/outputs connected, on the one hand, to the output of the first part of one odd die of the first group and to an input/output of a neighboring switch means, and on the other hand, to the input of the second part of one even die of the second group and to an input/output of another neighboring switch means.

11. Wafer according to claim 4, characterized in that each odd die of each first group is coupled to a first bus through a dedicated switch means, and each even die of each group is coupled to a second bus through a dedicated switch means.

12. Wafer according to claim 1, characterized in that said coupling means comprises at least one signal processing means arranged to apply at least one chosen signal processing to the first output signals delivered by a first part output, before they feed a second part input, and/or to the second output signals delivered by a second part output, before they feed a first part input.

13. Wafer according to claim 1, characterized in that said first and second complementary signal processing parts are chosen in a group comprising at least a transmitting path and a receiving path, a digital to analog converter and an analog to digital converter, or else a demodulator and a modulator.
